(19) United States
(12) Patent Application Publication
(10) Pub. No.: US 2025/0267789 A1
(43) Pub. Date: Aug. 21, 2025

(54) MATERIAL SHEET HAVING LCP FIBERS AND LOW-LOSS DIELECTRIC

(71) Applicant: LCP MEDICAL TECHNOLOGIES, LLC, Rogers, MN (US)

(72) Inventor: James Rathburn, Rogers, MN (US)

(21) Appl. No.: 19/057,032

(22) Filed: Feb. 19, 2025

Related U.S. Application Data
(60) Provisional application No. 63/555,336, filed on Feb. 19, 2024.

(51) Int. Cl. H05K 1/03; H05K 3/00

(52) U.S. Cl. CPC H05K 1/0366; H05K 3/0094; H05K 2201/0141; H05K 2201/0278; H05K 2201/029; H05K 2203/0554; H05K 2203/1147

(57) ABSTRACT

A material sheet for circuit board fabrication is provided. The material sheet includes liquid crystal polymer (LCP) fibers impregnated in a dielectric having a dissipation factor between 0.004 and 0.0002.

### RELATED APPLICATIONS

This application claims the benefit of U.S. Provisional Application No. 63/555,336, filed on Feb. 19, 2024, entitled “LIQUID CRYSTAL POLYMER FIBER OR FABRIC REINFORCED LOW LOSS LIQUID DIELECTRIC STRUCTURE WITH MELT BLOWN OR SPUN BOND PET, PP, CA, AND PA OPTIONS”, the contents of which are hereby incorporated herein by reference.

### BACKGROUND

The printed circuit fabrication industry has long used glass weave fabrics saturated with epoxy-type dielectric materials to create a reinforced laminate material that carries circuits and vertical connections to create a desired circuit stack. These materials are processed with conventional methods to pattern circuits, drill via locations, plate copper to connect layers and have many names such as FR4 and are produced by many suppliers. As signal integrity needs increase, the conventional laminate material sets encounter performance issues related to the resin used for saturation and glass weave reinforcement.

### BRIEF DESCRIPTION

A material sheet for circuit board fabrication is provided. The material sheet includes liquid crystal polymer (LCP) fibers impregnated in a dielectric having a dissipation factor between 0.004 and 0.0002.

### DRAWINGS

Understanding that the drawings depict only exemplary embodiments and are not therefore to be considered limiting in scope, the exemplary embodiments will be described with additional specificity and detail through the use of the accompanying drawings, in which:

FIGS. 1A and 1B are cross-sectional views of example stages in the manufacture of a high performance material sheet having liquid crystal polymer (LCP) fiber impregnated in low-loss dielectric;

FIG. 2 is a cross-sectional view of an example copper clad material shset that can be formed using any of the material sheets described herein;

FIG. 3 is a cross-sectional view of an example copper clad material sheet in which the top copper layer has a different thickness than the bottom copper layer;

FIG. 4 is a cross-sectional view of another example copper clad material sheet in which the top copper layer has a different thickness than the bottom copper layer;

FIG. 5 is a cross-sectional view of an example circuit sub-structures created by forming circuit patterns in a copper clad material sheet as described herein;

FIG. 6 is a cross-sectional view of another example circuit sub-structures created by forming circuit patterns in a copper clad material sheet as described herein;

FIGS. 7A and 7B are cross-sectional views of example stages in which laser-ablated features formed in a copper clad material sheet describe herein;

FIG. 8 is a cross-sectional view of a lamination process using copper clad material sheets as described herein;

FIGS. 9A and 9B are cross-sectional views of example stages of plating a copper clad material sheet as described herein; and

FIGS. 10A and 10B are cross-sectional views of example further stages of processing the structure from FIG. 9B.

### DETAILED DESCRIPTION

The subject matter discussed herein includes high performance material sheets for circuit board fabrication, such as Liquid Crystal Polymer fiber or fabric that is saturated with one of several types of low-loss dielectric liquid or film transfer materials. LCP fiber or fabric is commercially produced under the brand name Vectran (images below) and is a high-performance fabric or fiber used for applications that can benefit from the mechanical properties of LCP. This material also has excellent electric properties and, when combined with a low-loss dielectric, can leverage the principles of a reinforced laminate-type material along with very low signal loss and control of laminate thickness. In an example, the thickness of the material sheet is 100 microns or less, such as 50 microns or less, or 25 microns or less.

In other embodiments, melt blown or spun bond Polyester, Polypropylene, or Nylon can be saturated with a low-loss dielectric liquid or film transfer material to create a low-cost high, performance-reinforced laminate material that has lower performance than LCP at lower cost.

Example materials that can be used for the low-loss dielectric or film transfer include high-purity cyclic olefin-based materials, low-loss epoxy or thermoset type materials, raw resin, solvent adjusted, or cast film. “Low-loss” as used herein refers to materials having a dissipation factor DF of 0.004 to 0.0002. A lower DF value provides better performance. In one embodiment an LCP fiber matrix, mat, or fabric with a dissipation factor of 0.004 to 0.002 is saturated with a low loss dielectric with a dissipation factor of 0.001 or less, creating an aggregate loss factor less than the base fabric or fiber.

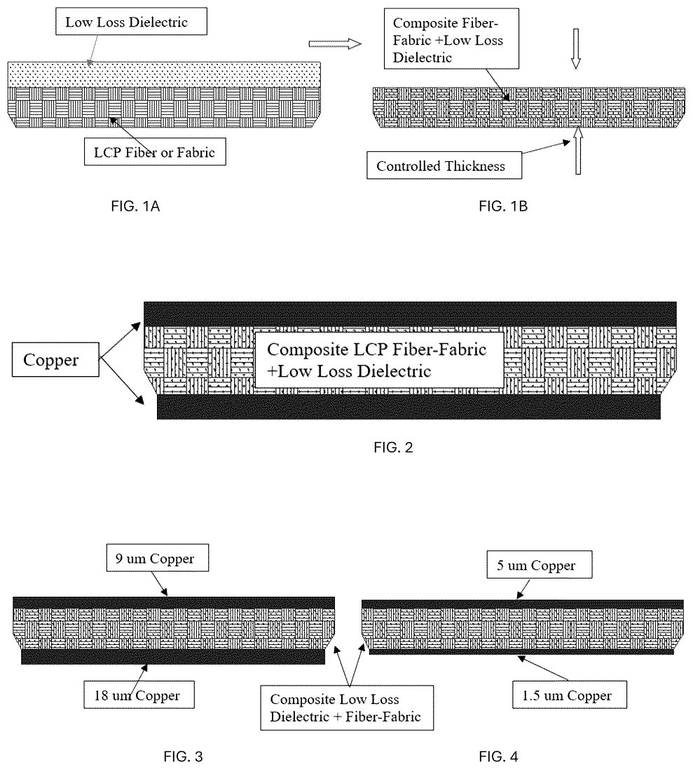

FIGS. 1A and 1B are cross-sectional views of example stages in the manufacture of a high performance material sheet for circuit board manufacturing as described herein. FIG. 1A shows a stage in which the an LCP fabric or collection of LCP fibers is located and arranged in a desired layer and a low-loss dielectric is applied. The low-loss dielectric can be in liquid form and applied in a number of methods such as inkjet printing, screen printing, ultra-sonic or spray coating, and dispensing. The dielectric may also be in solid, sheet, or cast form such that when processed, the material saturates the fiber-fabric field. FIG. 1B shows a resulting material sheet of LCP fibers-fabric plus low-loss dielectric after the combination is cured. The compliant or fluid nature of the pre-cured matrix provides some level of latitude with final thickness and matrix density. Fillers can be added to the low-loss dielectric prior to applying to the LCP fabric or fibers, such as PTFE powder, ceramics, or other desired materials to add mechanical or electric properties as desired.

In another embodiment, a mixture of LCP fibers and low-loss dielectric that can be deposited to create a material sheet when cured is formed.

In any case, the resulant material sheet can be fully cured at the desired thickness or partially cured to set the material and matrix in place but not fully cured such that the materia sheet can be used in further process steps that accomplish the final cure and acceptable bond to other layers such as copper or additional bonding layers or dielectric layers such as LCP or PTFE for example. Prepreg is commonly used in the laminated printed circuit industry to describe a mat or weave layer pre-impregnated with resin. The partially cured configuration of the material sheet described herein allows the material sheet to be laminated to other materials without adding a bond layer.

FIG. 2 is a cross-sectional view of an example copper clad material shset that can be formed using any of the material sheets described herein. As shown a copper foil can be added to one or both sides any of the material sheets described herein to form a copper clad circuit sub-structure. The copper layer(s) can be applied to the material sheet low-loss dielectric plus LCP Fiber-Fabric without the need for an additional bond or adhesive. In an example, both the top and bottom copper layers can have the same thickness as shown in FIG. 2. FIG. 3 is a cross-sectional view of an example in which the top copper layer has a different thickness (9 microns) than the bottom copper layer (18 microns). FIG. 4 is a cross-sectional view of another example in which the top copper layer has a different thickness (5 microns) than the bottom copper layer (1.5 microns).

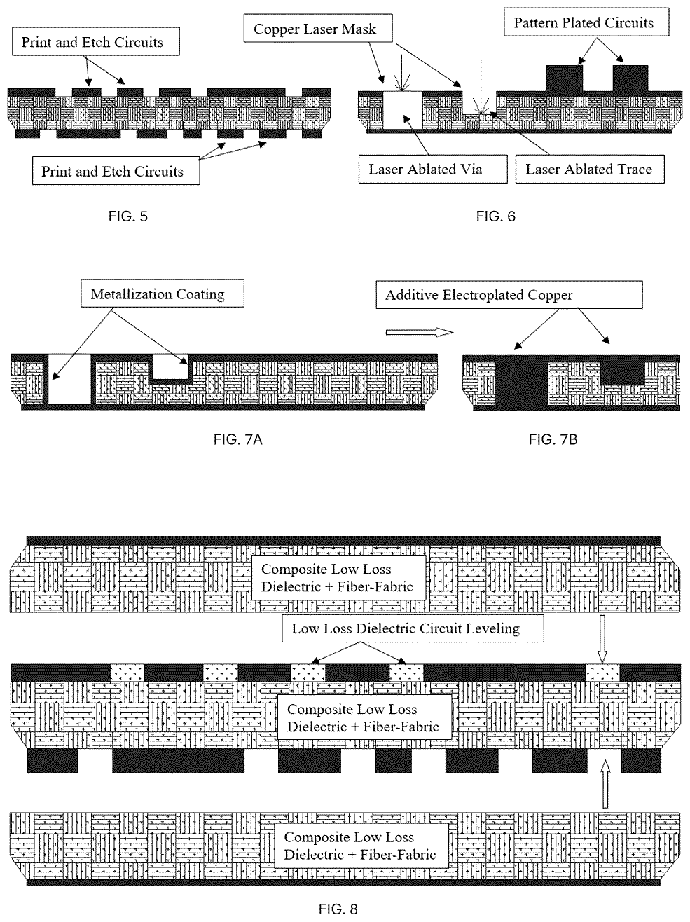

FIGS. 5 and 6 are cross-sectional views of example sub-structures created by forming circuit patterns in a copper clad material sheet as described herein. Existing printing and etching processes can be used to create circuit patterns and with thin copper processing to create vias, embedded traces, and resist-defined plated circuit patterns. For copper clad material sheets including LCP fabric or fiber, via locations and embedded trace locations can be formed with laser ablation at a low power setting UV, or with a Picosecond or excimer laser system. Laser ablation of material sheets containing glass requires a much different laser method to ablate the glass content vs resin only. The LCP content of the composite matrix allows for a low power setting with ablation characteristics very similar to those of the LCP content and the low loss dielectric content.

FIGS. 7A and 7B are cross-sectional views of example stages in which laser-ablated features formed in a copper clad material sheet describe herein, such as vias or traces, are metalized with electroless copper, palladium or carbon-based catalyst coating or metal inks such that when the electrical bus layer is connected and subjected to plating chemistry. As shown in FIG. 7B, a solid deposit of electroplated copper can be achieved from the bottom of the feature up to avoid closure of the feature with a resultant gap in plating.

FIG. 8 is a cross-sectional view of a lamination process using copper clad material sheets as described herein. The lamination process can be used to add layers to a copper clad material sheet described herein. As shown the copper clad material sheet having a copper layer on both sides has circuit features formed therein and is disposed between a second (upper) and third (lower) copper clad material sheet having a copper layer on a single side are laminated to respective sides of the middle copper clad material sheet. The upper and lower copper clad material sheet are in a semi-cured stage and are oriented such that the composite surface faces the middle copper clad material sheet and the copper layer faces away from the middle copper clad laminate. Thus, the composite surface of the upper and lower copper clad material sheet contacts the respective side of the middle copper clad laminate. In some examples, recesses between the traces in the middle copper clad laminate can be filled with the base low-loss dielectric to level the recesses and create a relatively even topographic profile on the exposed surface of the middle material sheet. Although only shown on the top side of the middle copper clad material sheet, in some examples recesses on both sides can be filled. Filling the recesses enables the LCP fiber-fabric content in the upper and lower copper clad material sheets to remain undeformed and in a low-stress condition post lamination. Without filling in the recesses, the topography of the pre-existing circuit pattern may cause difficulty in driving resin content into the recesses between the traces.

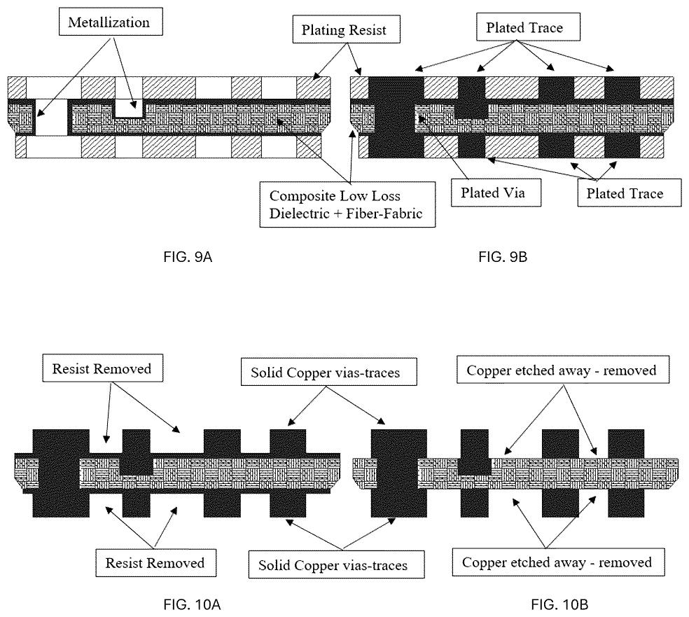

FIGS. 9A and 9B are cross-sectional views of example stages of plating a copper clad material sheet as described herein. In an example, both sides of the copper clad material sheet can be patterned with circuit structures and electroplated in a common process step. A thin metallization layer is present on both sides such that the electrolytic copper plating bus is connected to the thin metal layer and copper is plated into the open areas of both sides with metallization and not plated in areas where the resist is in place.

FIGS. 10A and 10B are cross-sectional views of example further stages of processing the structure from FIG. 9B. FIG. 10A shows the plating resist being stripped. FIG. 10B shows the circuit stack subjected to a micro-differential etch that removes the thin copper layer between the traces that served as the electrolytic plating bus connection.

Any of the fabrication stages herein can be repeated as many times as needed to create the final desired circuit stack, with the exposed outer layers top and bottom processed simultaneously through the lamination, laser, metallization, resist application and imaging, electroplating, stripping, and etch process. A final layer of material, less copper, can be applied and imaged or ablated to create a solder mask layer with terminals exposed for SMT soldering.

There are many benefits to the subject matter described herein. The use of a low-loss dielectric material to saturate an arrangement of LCP fibers or LCP fabric creates a very low-loss dielectric structure that is reinforced after curing for mechanical stability greater than extruded LCP film. The nature of the LCP fiber or LCP fabric combined with the low-loss dielectric creates a composite that is very conducive to laser ablation with UV, picosecond, or excimer processing without the challenge of ablating glass content. The subject matter described herein can also apply to other fabric or fiber materials that are normally not considered high performance, with the addition of the low loss dielectric substantially overcoming the higher loss characteristics of lesser performing fibers or fabrics such as PET, etc. The subject matter described herein can essentially turn many low-performing materials into a high-performance composite. The low loss dielectric can be a thermoset type material that can be partially cured, and bear pre-applied thin or thick coper layers depending on the desired processing needs. The low loss dielectirc plus LCP fiber or fabric compostie can be processed with conventional print and etch sequences as well as advanced additive or semi-additive processing for fine lines and spaces with tightly controlled impedance and low loss.

What is claimed is:

1. A material sheet including:
liquid crystal polymer (LCP) fibers impregnated in a dielectric having a dissipation factor between 0.004 and 0.0002.

2. The material sheet of claim 1, wherein the LCP fibers are a woven fabric.

3. The material sheet of claim 1, wherein the dielectric has a dissipation factor of 0.001 or less.

4. The material sheet of claim 1, wherein a thickness of the material sheet is 100 microns or less.

5. The material sheet of claim 1, wherein the material sheet is in a fully cured state.

6. The material sheet of claim 1, wherein the material sheet is in a partially cured state.

7. The material sheet of claim 1, having a first copper layer on a first side of the impregnated LCP fibers.

8. The material sheet of claim 7, having a second copper layer on a second side of the impregnated LCP fibers, the second copper layer having a different thickness than the first copper layer.

9. A method of fabricating a circuit board, the method comprising:
providing a material sheet comprised of liquid crystal polymer (LCP) fibers impregnated with a dielectric having a dissipation factor between 0.004 and 0.0002;
providing a copper layer on a first side of the material sheet; and
laser ablating the first side of the material sheet to form a cavity therein, wherein laser ablating includes using a picosecond or excimer laser system.

10. A method of fabricating a circuit board, the method comprising:
providing a first material sheet comprised of liquid crystal polymer (LCP) fibers impregnated with a dielectric having a dissipation factor between 0.004 and 0.0002, the first material sheet having a fully cured state;
providing a copper layer on a first side of the first material sheet; and
providing recesses between circuit traces in the copper layer on the first side of the first material sheet;
filling the recesses with dielectric;
providing a second material sheet comprised of liquid crystal polymer (LCP) fibers impregnated with a dielectric having a dissipation factor between 0.004 and 0.0002, the second material sheet having a partially cured state;
providing a copper layer on a first side of the second material sheet, wherein a second side of the second material sheet reverse of the first side of the second material sheet has no copper layer;
after filling the recesses in the first side of the first material sheet, laminating the second material sheet to the first side of the first material sheet, wherein the second side of the second material sheets contacts the first side of the first material sheet.

11. The method of claim 10, comprising:
providing a second copper layer on a second side of the first material sheet, the second side reverse of the first side of the first material sheet;
providing second recesses between circuit traces in the copper layer on the second side of the first material sheet;
filling the second recesses with dielectric;
providing a third material sheet comprised of liquid crystal polymer (LCP) fibers impregnated with a dielectric having a dissipation factor between 0.004 and 0.0002, the third material sheet having a partially cured state;
providing a copper layer on a first side of the third material sheet, wherein a second side of the third material sheet reverse of the first side of the second material sheet has no copper layer;
after filling the second recesses in the second side of the first material sheet, laminating the third material sheet to the second side of the first material sheet, wherein the second side of the third material sheets contacts the first side of the first material sheet.
